(19) United States
(12) Patent Application Publication
(10) Pub. No.: US 2009/0040075 A1
(43) Pub. Date: Feb. 12, 2009

(54) LIGHT-EMITTING KEYBOARD

(75) Inventors: CHANG-CHUN LIU, Shenzhen (CN); XIAO-LIN GAN, Shenzhen (CN); YU-KUANG HO, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 11/946,863

(22) Filed: Nov. 29, 2007

(30) Foreign Application Priority Data
Aug. 9, 2007 (CN) 200710201320.3

(51) Int. Cl. H03K 17/94

(52) U.S. Cl. 341/22

(57) ABSTRACT

An exemplary light-emitting keyboard includes an upper cover with a plurality of keystrokes, a printed circuit board, and a lower cover. The keyboard further includes a light guide plate, a reflector, and a light source. The light guide plate and reflector are arranged between the upper cover and the lower cover, and the light source is arranged beside the light guide plate and connected to the printed circuit board to get power. The light guide plate receives light beams from the light source and evenly distributes the light beams over the entire light guide plate through reflection and diffusion, and the reflector is disposed under the light guide plate for upwardly reflecting light beams from the light source to the light guide plate. Thus, the light-emitting keyboard can be used in a dark or gloomy environment.

### BACKGROUND

1. Field of the Invention

The present invention relates to keyboards, and particularly to a light-emitting keyboard.

2. Description of Related Art

A computer system includes many components, such as the central processing unit (or processor), temporary memory for storing program instructions (like random access memory, or RAM), a permanent storage device (such as a hard disk), and a variety of user interface devices, such as a video display, a keyboard, and a pointing device.

The keyboard may come in a variety of physical embodiments. Referring to FIG. 1, a conventional keyboard includes an upper cover 12 with a plurality of keystrokes 122, a rubber layer 14, a partitioning layer 16, a printed circuit board (PCB) 17 connected to the partitioning layer 16, and a lower cover 18. The PCB 17 is connected to a connector 174 via a cable 172 for coupling the keyboard to the computer system via the connector 174.

Keyboards are used in a variety of applications for entry of alphanumeric and other types of data into a computer system. But it is hard to use a keyboard in a dark or gloomy environment.

### SUMMARY

An exemplary light-emitting keyboard includes an upper cover with a plurality of keystrokes, a printed circuit board, and a lower cover. The keyboard further includes a light guide plate, a reflector, and a light source. The light guide plate and reflector are arranged between the upper cover and the lower cover, and the light source is arranged beside the light guide plate and connected to the printed circuit board to get power. The light guide plate receives light beams from the light source and evenly distributes the light beams over the entire light guide plate through reflection and diffusion, and the reflector is disposed under the light guide plate for upwardly reflecting light beams from the light source to the light guide plate.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is an exploded, isometric view of a conventional keyboard;

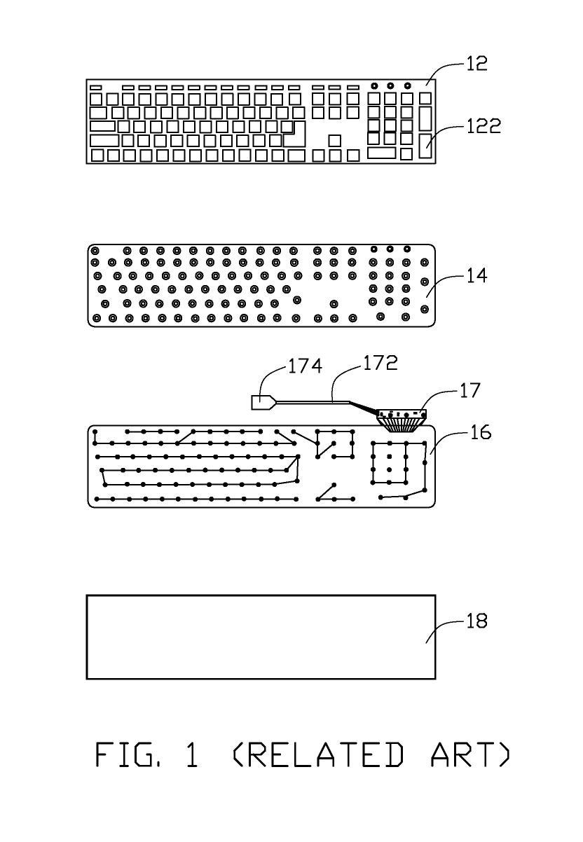

FIG. 2 is an exploded view of a light-emitting keyboard in accordance with the present invention;

FIG. 3 is an assembled view of FIG. 2; and

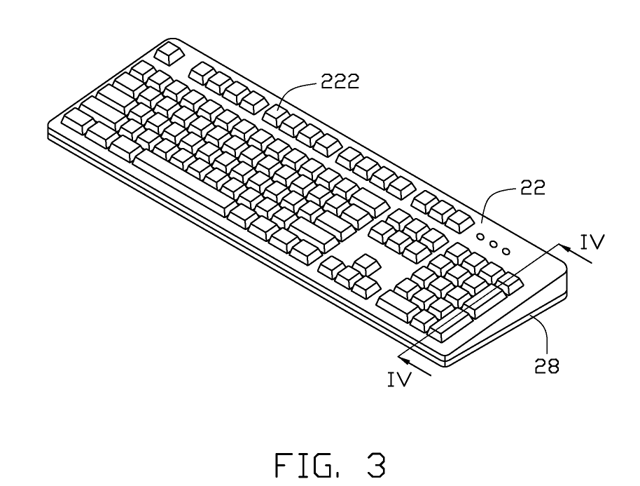

FIG. 4 is a cross-sectional view taken along line IV-IV of FIG. 3.

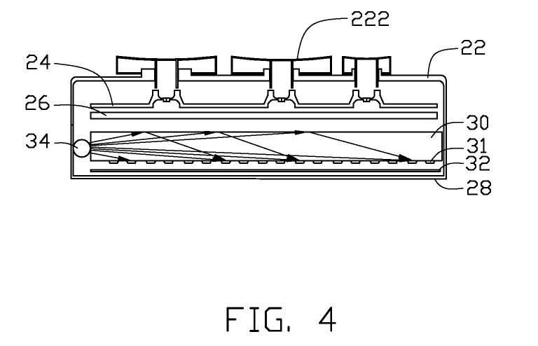

### DETAILED DESCRIPTION

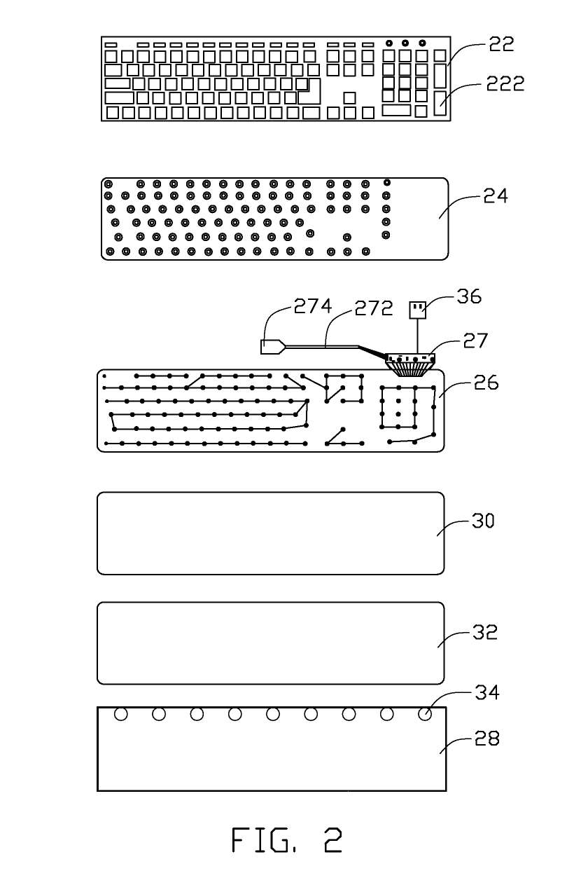

Referring to FIGS. 2˜4, a light-emitting keyboard in accordance with an embodiment of the present invention includes an upper cover 22 with a plurality of keystrokes 222, a rubber layer 24, a partitioning layer 26, a printed circuit board 27 connected to the partitioning layer 26, a light guide plate 30, a reflector 32 and a lower cover 28 in turn. The keyboard further includes a plurality of light emitting diodes (LEDs) 34 beside the light guide plate 30. The LEDs 34 are connected to the PCB 27 via a switch (not shown) to get power. The PCB 27 is connected to a connector 274 via a cable 272 for coupling the light-emitting keyboard to a computer system via the connector 274. The PCB 27 is further coupled with a transformer 36 to supply power to the LEDs 34 when the keyboard is not hardwired to a computer system such as in the case of a wireless connection or merely to have the keyboard light up when the computer system is shut off for decorative purposes.

The light guide plate 30 is configured for receiving light beams from the LEDs 34, and for evenly distributing the light beams over the entire light guide plate 30 through reflection and diffusion. The reflector 32 is disposed under the light guide plate 30 for upwardly reflecting light beams from the LEDs 34 to the light guide plate 30. The light guide plate 30 comprises a bottom surface on which a plurality of preferably round identical protrusions 31 is formed to diffuse light beams coming from the LEDs 34. The light guide plate 30 is made of acrylic material to provide a uniformly reflecting surface for guiding light. The upper cover 22 and the keystrokes 222 are made of transparent material to permit the light beams transmitting.

Therefore, users can turn on the LEDs 34 to make the keyboard emit light. Thus, the light-emitting keyboard can be used in a dark or gloomy environment.

The foregoing description of the exemplary embodiments of the invention has been presented only for the purposes of illustration and description and is not intended to be exhaustive or to limit the invention to the precise forms disclosed. Many modifications and variations are possible in light of the above teaching. The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A light-emitting keyboard comprising:
an upper cover with a plurality of keystrokes;
a printed circuit board (PCB) connected to a connector via a cable;
a lower cover;
a light guide plate and a reflector arranged between the upper cover and the lower cover; and
a light source arranged beside the light guide plate and connected to the PCB to receive power.

2. The light-emitting keyboard as claimed in claim 1, wherein the light guide plate receives light beams from the light source and evenly distributes the light beams over the entire light guide plate through reflection and diffusion, and the reflector is disposed under the light guide plate for upwardly reflecting light beams from the light source to the light guide plate.

3. The light-emitting keyboard as claimed in claim 2, wherein a plurality of protrusions is formed on a bottom surface of the light guide plate to diffuse light beams coming from the light source.

4. The light-emitting keyboard as claimed in claim 1, wherein the light source is an LED.

5. The light-emitting keyboard as claimed in claim 1, wherein the PCB is further connected to a transformer to receive power.

6. The light-emitting keyboard as claimed in claim 1, wherein the upper cover and the keystrokes are made of transparent material
